(19) United States
(12) Patent Application Publication
(10) Pub. No.: US 2026/0137010 A1
(43) Pub. Date: May 14, 2026

(54) PACKAGE STRUCTURE AND FABRICATION METHOD THEREOF

(71) Applicant: Taiwan Semiconductor Manufacturing Company, Ltd., Hsinchu (TW)

(72) Inventors: Po-Ching Wu, Hsinchu (TW); Chao-Wei Chiu, Hsinchu City (TW); Hsuan-Ting Kuo, Taichung City (TW); Meng-Tsan Lee, Hsinchu (TW); An-Jhih Su, Taoyuan City (TW); Hsiu-Jen Lin, Hsinchu County (TW)

(73) Assignee: Taiwan Semiconductor Manufacturing Company, Ltd., Hsinchu (TW)

(21) Appl. No.: 18/942,739

(22) Filed: Nov. 10, 2024

(51) Int. Cl. H01L 23/498; H01L 21/48; H01L 21/683; H01L 23/00; H01L 23/15; H01L 23/31; H01L 23/48; H01L 23/538; H01L 25/065; H01L 25/10

(52) U.S. Cl. CPC H10W 90/401; H10P 72/7402; H10W 20/20; H10W 70/05; H10W 70/095; H10W 70/65; H10W 70/685; H10W 70/692; H10W 74/117; H10W 90/00; H10W 70/60; H10W 74/10; H10W 90/701; H10W 90/724; H10W 90/794

(57) ABSTRACT

A package structure includes a stacked substrate structure and a first top die. The stacked substrate structure includes a first circuit substrate, a second circuit substrate stacked with the first circuit substrate, a first build-up structure located above the first circuit substrate, a bridge die bonding to the first build-up structure, an encapsulation layer disposed above the first build-up structure and laterally surrounding the bridge die and a redistribution structure disposed above the encapsulation layer and the bridge die. The bridge die includes a through semiconductor via electrically connecting the first build-up structure to the redistribution structure. The first top die is disposed above the stacked substrate structure and electrically connected with the redistribution structure.

### BACKGROUND

With the rapid advancement of semiconductor technology, the size of electronic devices is progressively becoming thinner and more compact. Generally, these electronic devices contain multiple chips with different functionalities. To further reduce the overall size of the electronic devices, multi-chip packaging techniques are commonly employed, integrating several chips into a single package. This approach not only effectively shortens the signal transmission paths between chips but also enhances the operational efficiency and performance of the devices. However, as the market demand for slimmer and more compact electronic devices continues to grow, the challenge of further reducing package size, increasing packaging density, and achieving better signal transmission efficiency without compromising device reliability has become a critical technical hurdle that major semiconductor manufacturers are eager to overcome.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a package structure in accordance of some embodiments of the disclosure.

FIGS. 2A to 2O are cross-sectional views of various steps of a fabrication method of a package structure in accordance of some embodiments of the disclosure.

FIG. 3 is a cross-sectional view of a package structure in accordance of some embodiments of the disclosure.

FIG. 4 is a cross-sectional view of a package structure in accordance of some embodiments of the disclosure.

FIG. 5 is a cross-sectional view of a package structure in accordance of some embodiments of the disclosure.

FIG. 6 is a cross-sectional view of a package structure in accordance of some embodiments of the disclosure.

FIGS. 7A to 7J are cross-sectional views of various steps of a fabrication method of a substrate stack in accordance of some embodiments of the disclosure.

FIG. 8 is a cross-sectional view of a package structure in accordance of some embodiments of the disclosure.

FIGS. 9A to 9E are cross-sectional views of various steps of a fabrication method of a substrate stack in accordance of some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain package structures, one or more dies are packaged over a package substrate, which not only supports the entire package structure but also provides a platform for circuit layout. The dies within the package structure are electrically connected to external devices via the package substrate. Typically, the package substrate includes a build-up structure with multiple circuit layers. As the integration level of the package structure increases, the build-up structure must incorporate more circuit layers to meet the growing demands of circuit layout. However, increasing the number of circuit layers in the build-up structure may result in a longer current transmission path between the dies and external devices (e.g., signal sources), which may negatively impact performance due to increased resistance and signal delay.

In some embodiments of the present disclosure, one or more embedded dies are embedded within the package substrate, rather than mounted above the top of the package substrate. This configuration significantly shortens the current transmission path between the embedded dies and external devices (e.g., signal sources), leading to improved performance with reduced signal delay and power consumption. By embedding the dies in the package substrate, the overall power integrity (PI) may be enhanced, and the system may achieve higher operational efficiency. This approach is particularly advantageous in high-performance computing applications where low latency and energy efficiency are critical. Furthermore, embedding the embedded dies within the substrate allows for a more compact package design, enabling further miniaturization of electronic devices without compromising on functionality or power efficiency.

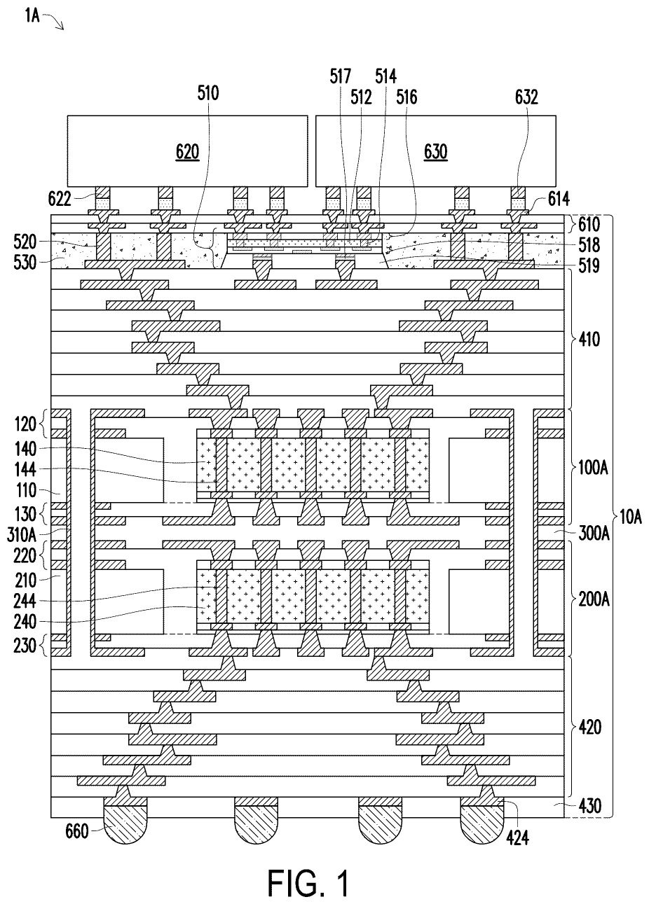

FIG. 1 is a cross-sectional view of a package structure 1A in accordance of some embodiments of the disclosure. Referring to FIG. 1, the package structure 1A includes a stacked substrate structure 10A, a first top die 620 and a second die 630. In FIG. 1, although only a first top die 620 and a second die 630 are shown above the stacked substrate structure 10A, the present disclosure is not limited thereto. In other embodiments, additional top dies may be included above the stacked substrate structure 10A. Furthermore, in some embodiments, an interposer may be positioned between the stacked substrate structure 10A and the top die(s), serving to electrically connect the top die(s) to the stacked substrate structure 10A.

The stacked substrate structure 10A includes a first circuit substrate 100A, a second circuit substrate 200A, a first build-up structure 410, a second build-up structure 420, an integrated circuit die 510, an encapsulation layer 530 and a redistribution structure 610.

The first circuit substrate 100A is stacked with the second circuit substrate 200A. The first circuit substrate 100A includes a first substrate 110, a first circuit structure 120, a second circuit structure 130 and a first embedded die 140. The first embedded die 140 is embedded in the first substrate 110. For example, the first substrate 110 has a first cavity, wherein the first cavity is filled with an insulation structure, and the first embedded die 140 is embedded in the insulation structure. The first circuit structure 120 is located over the first substrate 110 and the first embedded die 140, and the second circuit structure 130 is underlying the first substrate 110 and the first embedded die 140. In other word, the first substrate 110 and the first embedded die 140 are located between the first circuit structure 120 and the second circuit structure 130. In some embodiments, the first embedded die 140 includes first through-semiconductor vias 144 that penetrate the semiconductor substrate of the first embedded die 140, electrically connecting the first circuit structure 120 to the second circuit structure 130. In FIG. 1, one first embedded die 140 is embedded in the first substrate 110, but the disclosure is not limited thereto. In other embodiments, a plurality of first embedded dies 140 are embedded in the first substrate 110. For example, the first substrate 110 has a plurality of the first cavities, and the first embedded dies 140 are located in the first cavities.

The second circuit substrate 200A includes a second substrate 210, a third circuit structure 220, a fourth circuit structure 230 and a second embedded die 240. The second embedded die 240 is embedded in the second substrate 210. For example, the second substrate 210 has a second cavity, wherein the second cavity is filled with an insulation structure, and the second embedded die 240 is embedded in the insulation structure. The third circuit structure 220 is located over the second substrate 210 and the second embedded die 240, and the fourth circuit structure 230 is underlying the second substrate 210 and the second embedded die 240. In other word, the second substrate 210 and the second embedded die 240 are located between the third circuit structure 220 and the fourth circuit structure 230. In some embodiments, the second embedded die 240 includes second through-semiconductor vias 244 that penetrate the semiconductor substrate of the second embedded die 240, electrically connecting the third circuit structure 220 to the fourth circuit structure 230. In FIG. 1, one second embedded die 240 is embedded in the second substrate 210, but the disclosure is not limited thereto. In other embodiments, a plurality of second embedded dies 240 are embedded in the second substrate 210. For example, the second substrate 210 has a plurality of the second cavities, and the second embedded dies 240 are located in the second cavities.

In some embodiments, the first substrate 110 and the second substrate 210 may be referred to as core substrates. In certain instances, the first substrate 110 and the second substrate 210 are glass substrates. The advantages of glass substrate, including its high modulus, excellent flatness, and tunable coefficient of thermal expansion (CTE), contribute to reinforcing the substrate structure, expanding the process window, and enabling pitch scaling.

In some embodiments, the first embedded die 140 and the second embedded die 240 may include various semiconductor devices. For example, these dies might comprise integrated passive device (IPD) dies, integrated voltage regulator (IVR) dies, embedded deep trench capacitor (eDTC), active chip, and so forth. In certain instances, positioning the first embedded die 140 and the second embedded die 240 within core substrates may enhance the power integrity of the package structure. For instance, at least one of the first embedded die 140 or the second embedded die 240 may include a capacitor (e.g., a silicon capacitor). The capacitor may help compensate for or decouple “noise” caused by transient states from the power supply or other circuits, thereby enabling high-performance computing (HPC) with low power consumption.

A bonding layer 300A is located between the first circuit substrate 100A and the second circuit substrate 200A. The bonding layer 300A is used to attach the second circuit structure 130 of the first circuit substrate 100A to the third circuit structure 220 of the second circuit substrate 200A. In some embodiments, the bonding layer 300A includes an organic material or other adhesive materials. In FIG. 1, the stacked substrate structure 10A features the first circuit substrate 100A and the second circuit substrate 200A stacked together. However, this disclosure is not limited thereto. In other embodiments, the stacked substrate structure 10A may include additional circuit substrates, such as three or more stacked circuit substrates, with adjacent circuit substrates being bonded together using corresponding bonding layers.

In some embodiments, two or more core substrates (e.g., the first circuit substrate 100A and the second circuit substrate 200A) each embed capacitors (e.g., the first embedded die 140 and the second embedded die 240). These capacitors may work together to achieve high capacitance by summing the total capacitance of the individual capacitors. Additionally, stacking two or more core substrates (e.g., the first circuit substrate 100A and the second circuit substrate 200A) facilitates easier control of substrate warpage, especially with thinner core thicknesses. For example, the thickness of each core substrate, such as the first circuit substrate 100A and the second circuit substrate 200A, may be less than or equal to 1 mm, with ranges including 0.1 mm to 1 mm, 0.3 mm to 1 mm, 0.5 mm to 1 mm, or 0.7 mm to 1 mm. This approach provides flexibility for embedding both thin and thick capacitors within the cores.

A plurality of first through substrate vias 310A extend through the first circuit substrate 100A, the bonding layer 300A and the second circuit substrate 200A. In this embodiment, the first through substrate vias 310A extend through the first substrate 110, the first circuit structure 120, the second circuit structure 130, the bonding layer 300A, the second substrate 210, the third circuit structure 220 and fourth circuit structure 230. The first through substrate vias 310A electrically connect the second circuit substrate 200A to the first circuit substrate 100A.

The first build-up structure 410 is located above the first circuit substrate 100A. For instance, the first build-up structure 410 is disposed on and electrically connected to the first circuit structure 120 of the first circuit substrate 100A. The first build-up structure 410 includes multiple layers of conductive and dielectric materials, with the conductive layers being interconnected through conductive vias at different levels.

The integrated circuit die 510 is bonded to the first build-up structure 410. For example, the topmost conductive layer of the first build-up structure 410 includes conductive pads, to which the integrated circuit die 510 is attached to establish electrical connections with the first build-up structure 410.

In some embodiments, the integrated circuit die 510 is a bridge die. In certain cases, the bridge die may be devoid of active and/or passive components. Conversely, in other embodiments, the bridge die may include active and/or passive components. For instance, the integrated circuit die 510 includes a semiconductor substrate 512, a first interconnecting structure 516, and a second interconnecting structure 518. The first interconnecting structure 516 and the second interconnecting structure 518 are located on opposite sides of the semiconductor substrate 512. The first interconnecting structure 516 and the second interconnecting structure 518 each comprise one or more metal layers and one or more dielectric layers. The second interconnecting structure 518 is connected to the first build-up structure 410 through connection terminals 517. In some embodiments, the connection terminals 517 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. An underfill material 519 surrounds the connection terminals 517 and is located between the second interconnecting structure 518 and the first build-up structure 410. In some embodiments, the integrated circuit die 510 includes through-semiconductor vias 514 that extend through the semiconductor substrate 512, electrically connecting the first interconnecting structure 516 to the second interconnecting structure 518.

The encapsulation layer 530 is disposed above the first build-up structure 410 and laterally surrounding the integrated circuit die 510. The integrated circuit die 510 is embedded in the encapsulation layer 530. In some embodiments, through insulation vias 520 are disposed on the topmost conductive layer of the first build-up structure 410 and are embedded in the encapsulation layer 530. In some embodiments, the encapsulation layer 530 includes a molding compound, a molding underfill, a resin (such as epoxy), or the like.

The redistribution structure 610 is disposed above the integrated circuit die 510, the through insulation vias 520 and the encapsulation layer 530. The through semiconductor via 514 of the integrated circuit die 510 and the through insulation vias 520 in the encapsulation layer 530 electrically connecting the first build-up structure 410 to the redistribution structure 610.

The second build-up structure 420 is located under the second circuit substrate 200A. For instance, the second build-up structure 420 is disposed on and electrically connected to the fourth circuit structure 230 of the second circuit substrate 200A. The second build-up structure 420 includes multiple layers of conductive and dielectric materials, with the conductive layers being interconnected through conductive vias at different levels.

A protection layer 430 and a plurality of conductive terminals 660 are disposed on the second build-up structure 420. In some embodiments, the conductive terminals 660 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. In some embodiments, protection layer 430 is a solder resist layer.

The first top die 620 and the second top die 630 are disposed above and electrically connected with the stacked substrate structure 10A. The first top die 620 and the second top die 630 are connected to the redistribution structure 610 through the first connectors 622 and the second connectors 632, respectively. In some embodiments, the first connectors 622 and the second connectors 632 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like.

The first top die 620 and the second top die 630 may be system on chip (SOC) devices or system on integrated circuit (SoIC) devices. For example, the first top die 620 and the second top die 630 may include a logic die (e.g., central processing unit, microcontroller, etc.), a memory die (e.g., dynamic random access memory (DRAM) die, a static random access memory (SRAM) die, a high bandwidth memory (HBM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like, or a combination thereof.

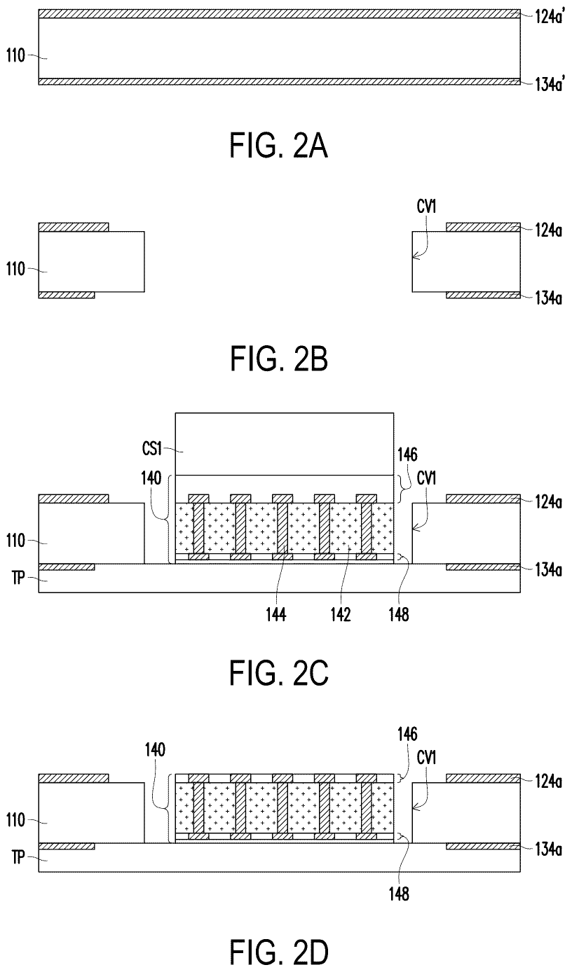

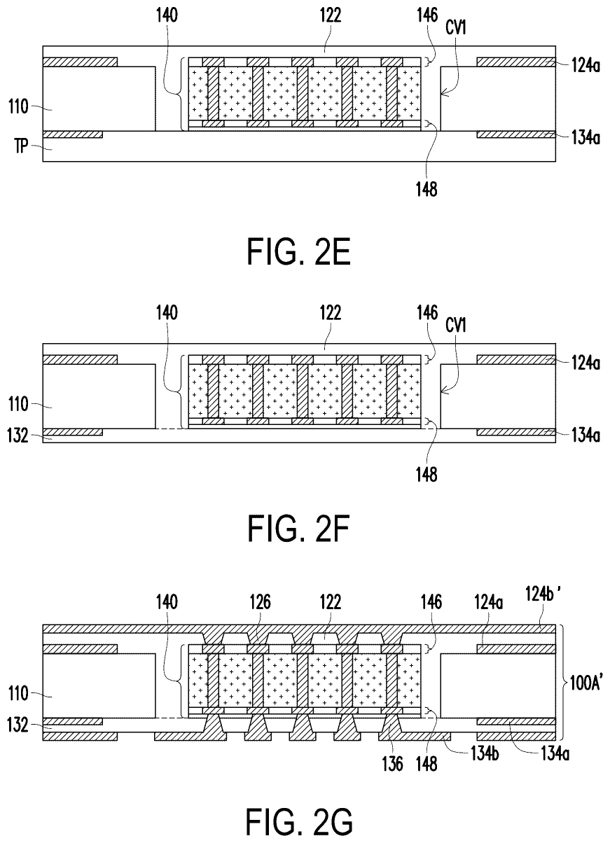

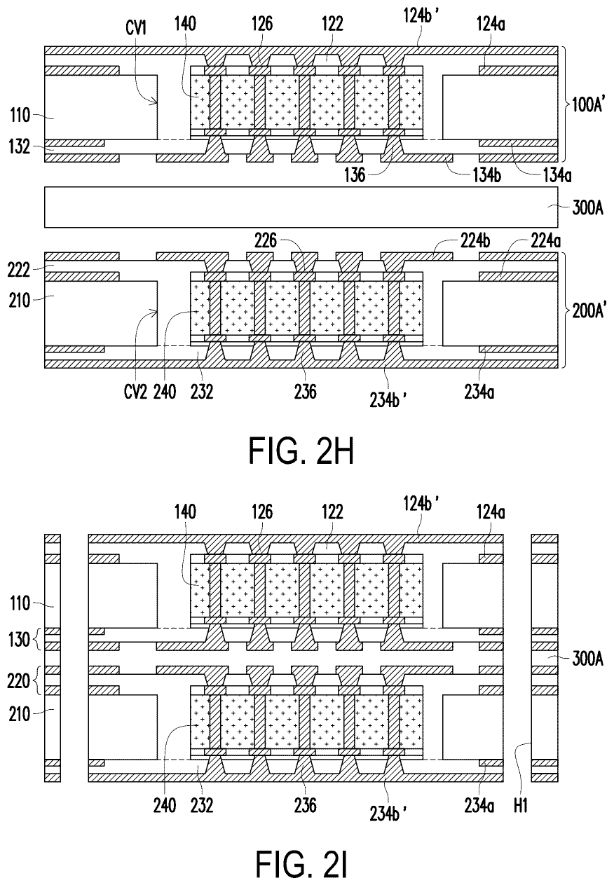

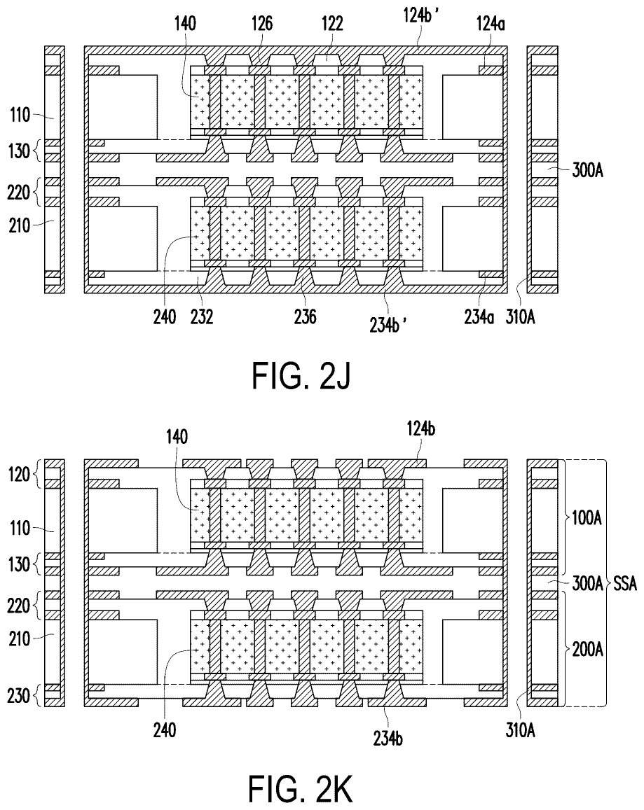

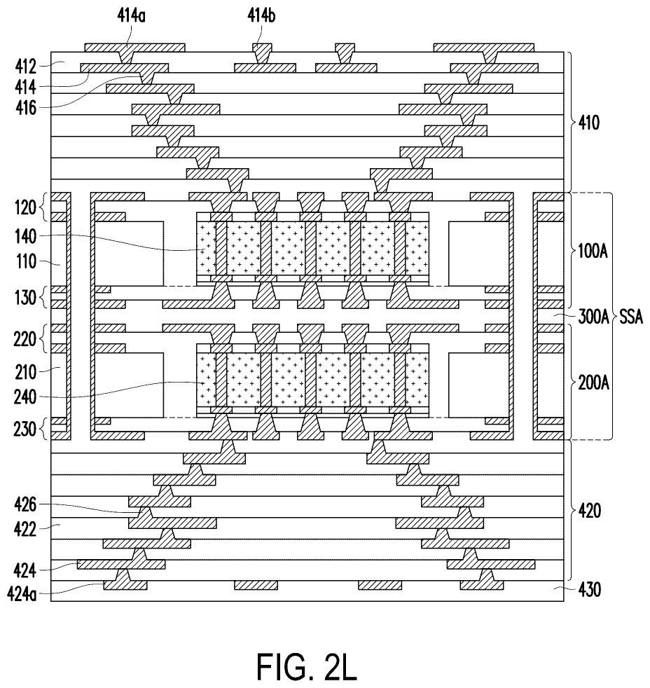

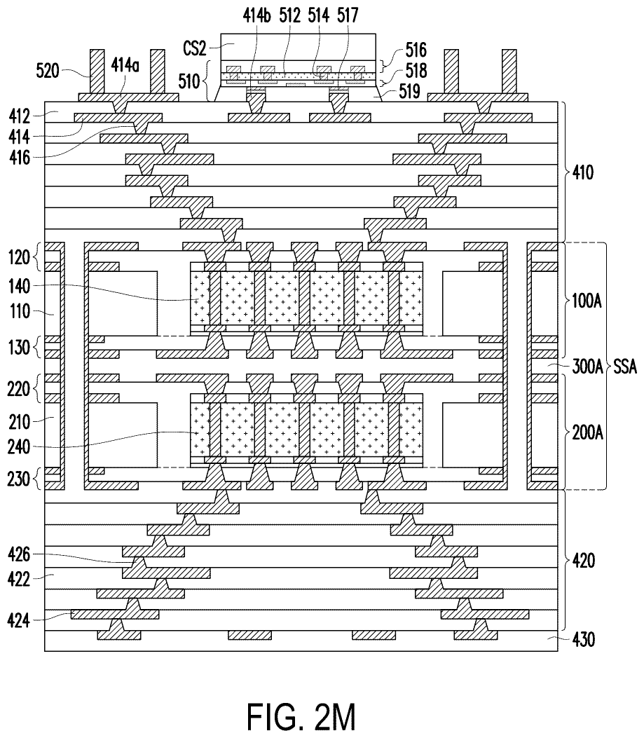

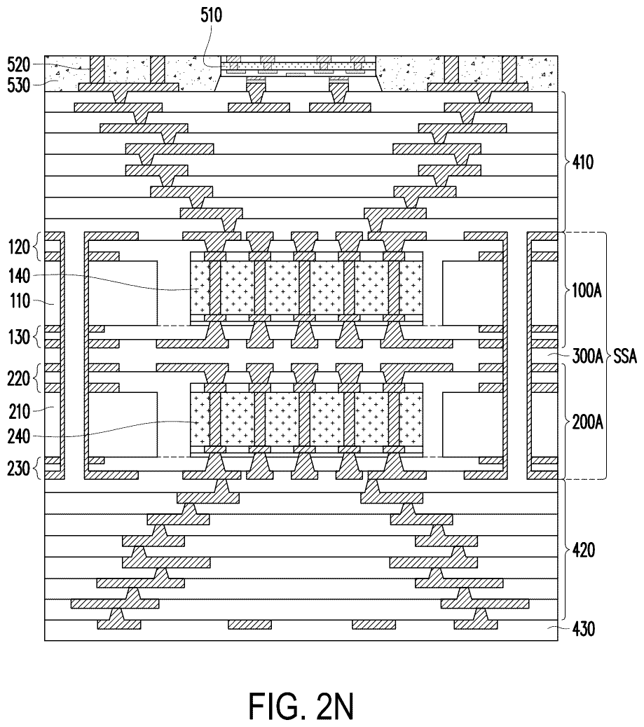

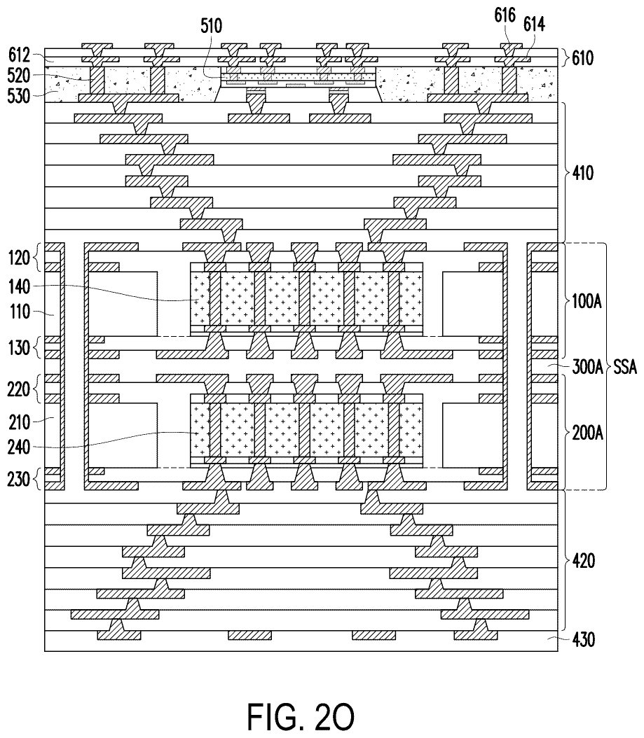

FIGS. 2A to 2O are cross-sectional views of various steps of a fabrication method of a package structure 1A in accordance of some embodiments of the disclosure. Referring to FIG. 2A, a first substrate 110 is provided. In some embodiments, the first substrate 110 is a glass substrate. A first conductive material layer 124a′ and a second conductive material layer 134a′ are respectively formed on opposite sides of the first substrate 110.

Referring to FIG. 2B, the first conductive material layer 124a′ and the second conductive material layer 134a′ are patterned to form a first conductive layer 124a and a second conductive layer 134a with the desired circuit layout. For example, the first conductive layer 124a and the second conductive layer 134a may be formed by etching copper layer or other conductive material layers.

A first cavity CV1 is formed in the first substrate 110. For instance, the first cavity CV1 may be created through laser drilling, mechanical drilling, etching, or other suitable methods that penetrate the first substrate 110. The width and shape of the first cavity CV1 may be adjusted according to requirements.

Referring to FIG. 2C, a first embedded die 140 is placed in the first cavity CV1. For example, a tape TP is bonded to the first substrate 110, and then the first embedded die 140 is bonded to the tape TP and aligned with the position of the first cavity CV1 through a pick-and-place (PnP) process.

In some embodiments, the first embedded die 140 includes a semiconductor substrate 142, a first interconnecting structure 146, and a second interconnecting structure 148. The first interconnecting structure 146 and the second interconnecting structure 148 are located on opposite sides of the semiconductor substrate 142. Both the first and second interconnecting structures 146 and 148 comprise one or more metal layers and one or more dielectric layers. The second interconnecting structure 148 is bonded to the tape TP. In some embodiments, the first embedded die 140 includes through-semiconductor vias 144 that extend through the semiconductor substrate 142, electrically connecting the first interconnecting structure 146 to the second interconnecting structure 148.

In some embodiments, the metal layers in the second interconnecting structure 148 are encapsulated by the insulating layer, preventing the metal layers in the second interconnecting structure 148 from directly contacting the tape TP. However, this disclosure is not limited thereto. In other embodiments, the metal layers in the second interconnecting structure 148 may directly contact the tape TP.

In some embodiments, a carrier substrate CS1 is positioned on top of the first embedded die 140. For example, the carrier substrate CS1 is bonded to the first interconnecting structure 146 of the first embedded die 140. In certain embodiments, the carrier substrate CS1 is attached to the first embedded die 140 through hybrid bonding, fusion bonding, adhesion, or other suitable methods. The presence of the carrier substrate CS1 helps reduce the likelihood of damage to the first embedded die 140 during the PnP process.

Referring to FIG. 2D, a grinding process is performed to remove the carrier substrate CS1 and to expose the uppermost metal layer in the first interconnecting structure 146. In some embodiments, a portion of the dielectric layer within the first interconnecting structure 146 may also be removed during the grinding process. In other embodiments, if the uppermost metal layer in the first interconnecting structure 146 has already been exposed when the first embedded die 140 was placed on the tape TP, the grinding process may be omitted.

Referring to FIG. 2E, a first insulation structure 122 is formed within the first cavity CV1, surrounding the first embedded die 140. The first insulation structure 122 is positioned above the first conductive layer 124a and the first embedded die 140. A portion of the first insulation structure 122 fills the gap between the first embedded die 140 and the first substrate 110, and is laterally located between a sidewall of the first cavity CV1 and the first embedded die 140.

Referring to FIG. 2F, the tape TP is removed. In some embodiments, a portion of the tape TP may remain on the second interconnecting structure 148, though this disclosure is not limited thereto. In other embodiments, the tape TP is completely removed.

Next, a second insulation structure 132 is formed on the second interconnecting structure 148, the first insulation structure 122, and the second conductive layer 134a. In some embodiments, the second insulation structure 132 integrates with the first insulation structure 122.

Referring to FIG. 2G, a third conductive material layer 124b′ is formed above the first insulation structure 122. In some embodiments, multiple openings are first created in the first insulation structure 122 to expose the first interconnecting structure 146 of the first embedded die 140. In some instances, some of these openings expose the first conductive layer 124a. The third conductive material layer 124b′ is then deposited in these openings and over the first insulation structure 122, so as to form the through conductive vias 126 connected to the first embedded die 140 (and the first conductive layer 124a).

On the other hand, a fourth conductive layer 134b is formed on the second insulation structure 132. For example, multiple openings are first created in the second insulation structure 132 to expose the second interconnecting structure 148 of the first embedded die 140. In some instances, some of these openings expose the second conductive layer 134a. A fourth conductive material layer is then deposited in these openings and over the second insulation structure 132, so as to form through conductive vias 136 connected to the first embedded die 140 (and the second conductive layer 134a). Finally, the fourth conductive material layer is patterned to form the fourth conductive layer 134b.

After forming the third conductive material layer 124b′ and the fourth conductive layer 134b, a first work piece 100A′ is obtained. The first work piece 100A′ is a partially completed version of the first circuit substrate 100A (see FIG. 1). In some embodiments, the work piece 100A′ may include additional conductive layer(s). For example, the third conductive material layer 124b′ may be patterned, and one or more dielectric layers and conductive layers may be formed on the patterned third conductive material layer 124b′. Alternatively, additional dielectric layers and conductive layers may be formed on the fourth conductive layer 134b.

Referring to FIG. 2H, a second work piece 200A′ is provided. The second work piece 200A′ is a partially completed version of the second circuit substrate 200A (see FIG. 1). The second work piece 200A′ includes a second substrate 210, a second embedded die 240, a fifth conductive layer 224a, a sixth conductive layer 234a, a third insulation structure 222, a fourth insulation structure 232, a seventh conductive layer 224b, and an eighth conductive material layer 234b′. In some embodiments, the method for forming the second work piece 200A′ is similar to the method used to form the first work piece 100A′.

The second substrate 210 includes one or more second cavities CV2. The fabrication method of the second substrate 210 is similar to the fabrication method of the first substrate 110 in the first work piece 100A′. The number, shape, and position of the second cavities CV2 in the second substrate 210 may be the same as or different from those of the first cavity CV1 in the first substrate 110.

A fifth conductive layer 224a and a sixth conductive layer 234a are located on opposite sides of the second substrate 210, respectively.

The second embedded die 240 is positioned within the second cavity CV2. The method for embedding the second embedded die 240 into the second substrate 210 is similar to the method used for embedding the first embedded die 140 into the first substrate 110. In some embodiments, the second embedded die 240 and the first embedded die 140 may contain dies with similar or different functionalities.

The third insulation structure 222 fills the gap between the second embedded die 240 and the second substrate 210 and laterally surrounds the second embedded die 240. The third insulation structure 222 covers the fifth conductive layer 224a. The fourth insulation structure 232 is formed on the second substrate 210 and covers the sixth conductive layer 234a. In some embodiments, the methods for forming the third insulation structure 222 and the fourth insulation structure 232 are similar to those used for forming the first insulation structure 122 and the second insulation structure 132.

The seventh conductive layer 224b is located on top of the third insulation structure 222 and electrically connects to the second embedded die 240 and/or the fifth conductive layer 224a through conductive vias 226. The eighth conductive material layer 234b′ is formed on the fourth insulation structure 232 and electrically connects to the second embedded die 240 and/or the sixth conductive layer 234a through conductive vias 236.

The first substrate 110 is bonded to the second substrate 210 through the bonding layer 300A. More specifically, the first work piece 100A′ is bonded to the second work piece 200A′ through the bonding layer 300A. In some embodiments, the outermost conductive layer of the first work piece 100A′ (i.e., the fourth conductive layer 134b) and the outermost conductive layer of the second work piece 200A′ (i.e., the seventh conductive layer 224 b) are embedded within the bonding layer 300A.

Referring to FIG. 2I, after bonding and stacking the first work piece 100A′ and the second work piece 200A′, multiple through holes H1 are formed that pass through the first work piece 100A′, the second work piece 200A′, and the bonding layer 300. In some embodiments, the second embedded die 240 overlaps with the first embedded die 140, which increases the area available for forming the through holes H1. However, the disclosure is not limited thereto. In other embodiments, the second embedded die 240 does not overlap with the first embedded die 140. The formation of the through holes H1 may involve one or more laser processes or other drilling processes.

Referring to FIG. 2J, a conductive material is filled into the through holes H1 to form the first through substrate vias 310A. The conductive material is deposited on the sidewalls of the through holes H1, extending from the outermost layer of the first work piece 100A (i.e., the third conductive material layer 124b′) to the outermost layer of the second work piece 200A′ (i.e., the eighth conductive material layer 234b′). The conductive material may completely fill or partially fill the through holes H1.

Referring to FIG. 2K, the third conductive material layer 124b′ and the eighth conductive material layer 234b′ are patterned to form the third conductive layer 124b and the eighth conductive layer 234b, respectively. At this stage, a substrate stack SSA including the first circuit substrate 100A and the second circuit substrate 200A is completed.

Referring to FIG. 2L, the first build-up structure 410 is formed above the first substrate 110 and the second substrate 210, and the second build-up structure 420 is formed under the first substrate 110 and the second substrate 210. The first build-up structure 410 and the second build-up structure 420 are formed respectively on opposing sides of the substrate stack SSA.

The first build-up structure 410 comprises insulating sub-layers 412, metal layers 414, and vias 416. The second build-up structure 420 comprises insulating sub-layers 422, metal layers 424, and vias 426. For example, the metal layers 414 and 424 may include metal routing lines, pads, or contacts. In some embodiments, the topmost metal layer 414 includes pads 414a and 414b, while the bottommost metal layer 424 includes pads 424a. The metal layers 414 and 424, along with the vias 416 and 426 embedded in the corresponding insulating sub-layers 412 and 422, are electrically interconnected to provide electrical connections for the first build-up structure 410 and the second build-up structure 420.

In some embodiments, the insulating sub-layers 412 and 422 may be made of any suitable material, including polymeric materials, ceramic materials, plastics, composite materials, liquid crystal polymers (LCPs), epoxy laminates of fiberglass sheets, prepregs, compounds of glass filler and resin such as Ajinomoto Build-up Film (ABF), or combinations thereof. The insulating sub-layers 412 and 422 may be formed by deposition, lamination, or any other suitable technique.

In some embodiments, the metal layers 414 and 424 may be composed of electrically conductive metals, such as copper, aluminum, silver, or similar materials, and deposited through plating processes, including electroplating or electroless plating. These metal layers may also be patterned to form various configurations to facilitate the routing of power and transmission of input/output (I/O) signals and to route signals and power through the package structure.

It should be noted that the number of build-up layers illustrated in FIG. 2L is for the sake of brevity. From a manufacturing perspective, the first build-up structure 410 and the second build-up structure 420 may comprise more or fewer build-up layers, and the number and thickness of each build-up layer may be adjusted according to design requirements.

Referring to FIG. 2M, conductive columns 520 are formed over the pads 414a. For example, the conductive columns 520 may be formed over the pads 414a using a plating process. In other embodiments, the conductive columns 520 may be placed on the pads 414a and bonded to the pads 414a through an adhesive layer.

The integrated circuit die 510 is bonded to the first build-up structure 410. For example, the integrated circuit die 510 is connected to the pads 414b via connection terminals 517. After bonding the integrated circuit die 510 to pads 414b, an underfill material 519 is introduced between the integrated circuit die 510 and the first build-up structure 410.

In some embodiments, the integrated circuit die 510 is bonded to the first build-up structure 410 with a carrier substrate CS2. For example, the carrier substrate CS2 is attached to the first interconnecting structure 516 of the integrated circuit die 510. In certain embodiments, the carrier substrate CS2 is bonded to the integrated circuit die 510 using hybrid bonding, fusion bonding, adhesion, or other suitable methods. The presence of the carrier substrate CS2 helps to mitigate the risk of damage to the integrated circuit die 510 during the fabrication process.

Referring to FIG. 2N, a planarization process is performed on the top of the structure, making the top surfaces of the integrated circuit die 510, the conductive columns 520, and the encapsulation layer 530 coplanar. In some embodiments, the planarization process may include a chemical mechanical polishing (CMP) process, a grinding process, a dry polishing process, an etching process, one or more other applicable processes, or a combination thereof. The carrier substrate CS2 is removed during the planarization process.

Referring to FIG. 2O, the redistribution structure 610 is formed above the integrated circuit die 510, the conductive columns 520, and the encapsulation layer 530. In some embodiments, the redistribution structure 610 includes dielectric layers 612 stacked in alternation with metallization layers 614. In some embodiments, the dielectric layers 612 and the metallization layers 614 are sequentially formed over the integrated circuit die 510, the conductive columns 520, and the encapsulation layer 530. In some embodiments, the metallization layers 614 each includes routing conductive traces and vias 616. In some embodiments, the bottommost metallization layer 614 is physically connected with the integrated circuit die 510 and the conductive columns 520.

Referring back to FIG. 1, the first top die 620 and the second top die 630 are provided over the stacked substrate structure 10A. The first top die 620 and the second top die 630 are bonded to and electrically connected to the redistribution structure 610 through the first connectors 622 and the second connectors 632, respectively. The conductive terminals 660 are formed on the second build-up structure 420, connecting to the lowest metal layers 424 in the second build-up structure 420 through openings in the protection layer 430. In some embodiments, the topmost metallization layer 614 in the redistribution structure 610 and the lowest metal layers 424 in the second build-up structure 420 may be under ball metallurgy (UBM) patterns or other conductive structures suitable for bonding processes.

In some embodiments, after bonding the first top die 620, the second top die 630, and the conductive terminals 660 to the stacked substrate structure 10A, a dicing process is performed to achieve the desired dimensions of the package structure 1A.

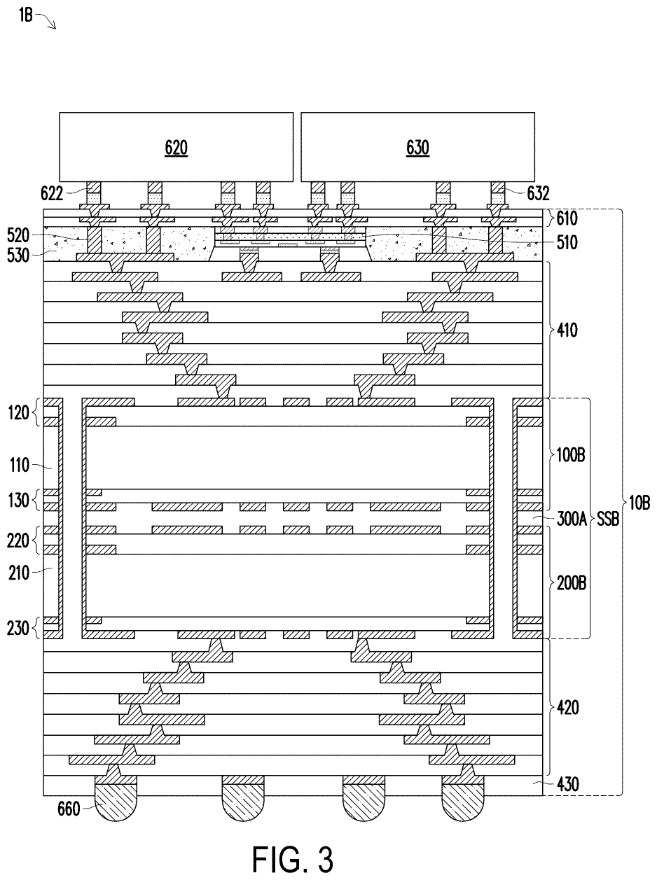

FIG. 3 is a cross-sectional view of a package structure 1B in accordance of some embodiments of the disclosure. The structure of the package structure 1B in FIG. 3 is similar to that of the package structure 1A in FIG. 1, with the difference being that: in the package structure 1B, neither the first circuit substrate 100B nor the second circuit substrate 200B contains embedded dies. The first circuit substrate 100B and the second circuit substrate 200B are stacked together to form the substrate stack SSB. The stacked substrate structure 10B includes the substrate stack SSB, the first build-up structure 410, the second build-up structure 420, the integrated circuit die 510, the through insulation vias 520, the encapsulation layer 530, and the redistribution structure 610.

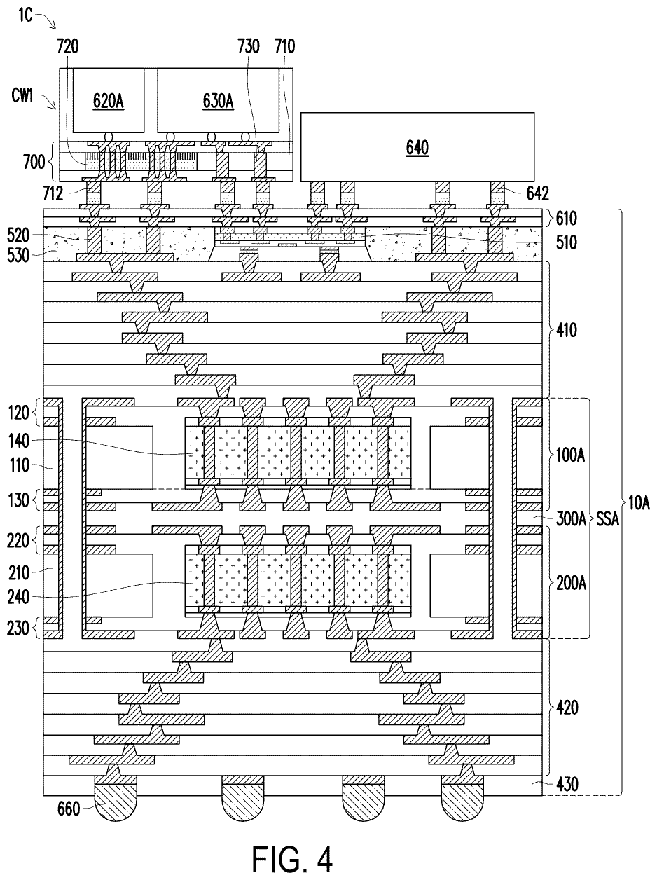

FIG. 4 is a cross-sectional view of a package structure 1C in accordance with some embodiments of this disclosure. The structure of the package structure 1C in FIG. 4 is similar to that of the package structure 1A in FIG. 1, with the difference being that: in the package structure 1C, the first top die 620A and the second top die 630A are integrated into a chip-on-wafer (CoW) package CW1. The first top die 620A and the second top die 630A are bonded to an interposer 700, and further electrically connected to the redistribution structure 610 through the interposer 700. The interposer 700 is located between both the first and second top dies 620A, 630A and the stacked substrate structure 10A.

In some embodiments, the interposer 700 includes an insulating layer 710, which laterally encapsulates a local silicon interconnect die (LSI) 720 and through insulation vias (TIV) 730. The interposer 700 also includes a front-side redistribution structure and a backside redistribution structure. The first top die 620A and the second top die 630A are bonded to the front-side redistribution structure of the interposer 700, while the backside redistribution structure of the interposer 700 is bonded to the redistribution structure 610. In this embodiment, the backside redistribution structure of the interposer 700 is connected to the redistribution structure 610 through connecting terminals 712. These connecting terminals 712 may be ball grid array (BGA) connectors, solder balls, metal pillars, controlled collapse chip connection (C4) bumps, micro bumps, electroless nickel-electroless palladium-immersion gold (ENEPIG) technique-formed bumps, or similar structures. In other embodiments, the backside redistribution structure of the interposer 700 is bonded to the redistribution structure 610 through hybrid bonding or other suitable process.

A third top die 640 is bonding to the redistribution structure 610 through third connectors 642. In some embodiments, the first top die 620A, the second top die 630A and the third top die 640 may be system on chip (SOC) devices or system on integrated circuit (SoIC) devices. For example, the first top die 620A, the second top die 630A and the third top die 640 may include a logic die (e.g., central processing unit, microcontroller, etc.), a memory die (e.g., dynamic random access memory (DRAM) die, a static random access memory (SRAM) die, a high bandwidth memory (HBM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), the like, or a combination thereof.

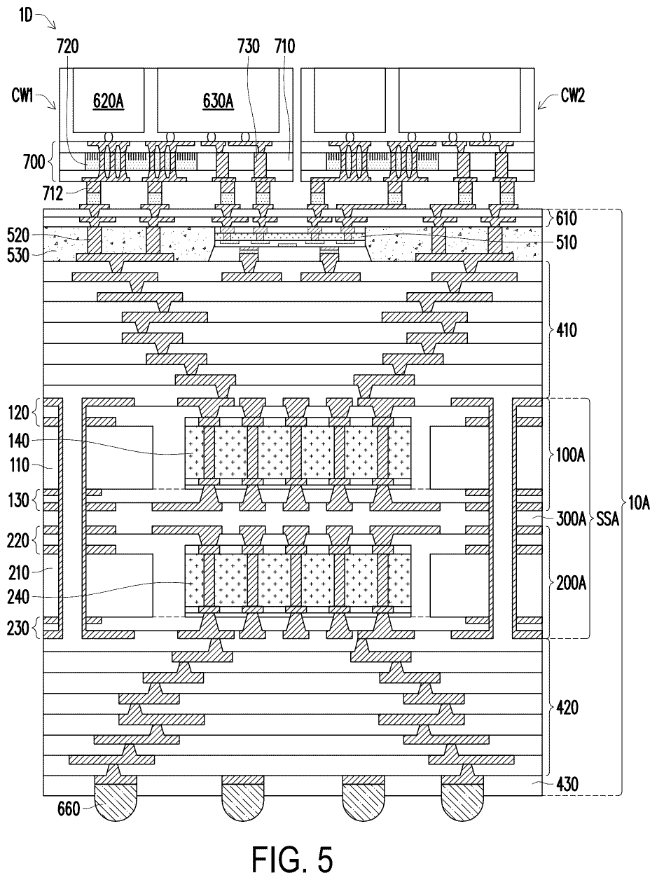

FIG. 5 is a cross-sectional view of a package structure 1D in accordance with some embodiments of this disclosure. The structure of the package structure 1D in FIG. 5 is similar to that of the package structure 1C in FIG. 4, with the difference being that: in the package structure 1D, multiple CoW packages CW1 and CW2 are included. The CoW packages CW1 and CW2 are bonded to the redistribution structure 610. In some embodiments, the CoW packages CW1 and CW2 may include power modules, photonic modules, or other similar types of modules.

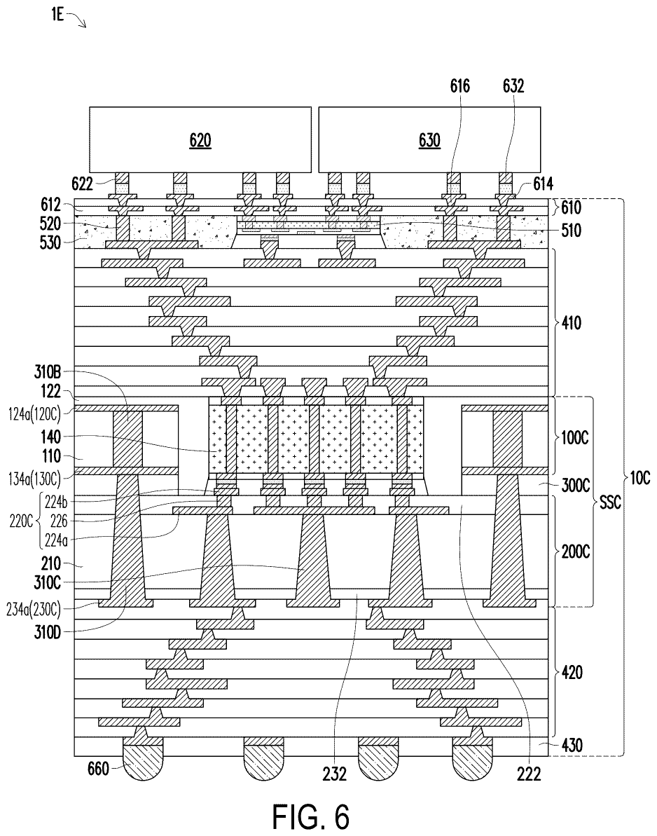

FIG. 6 is a cross-sectional view of a package structure 1E in accordance of some embodiments of the disclosure. The structure of the package structure 1E in FIG. 6 is similar to that of the package structure 1A in FIG. 1, with the difference being that: in the package structure 1E, the second circuit substrate 200C does not contain embedded dies. The first circuit substrate 100C and second circuit substrate 200C are stacked together to form the substrate stack SSC, wherein a bonding layer 300C is located between the first circuit substrate 100C and the second circuit substrate 200C. The stacked substrate structure 10C includes the substrate stack SSC, the first build-up structure 410, the second build-up structure 420, the integrated circuit die 510, the through insulation vias 520, the encapsulation layer 530, and the redistribution structure 610.

Referring to FIG. 6, the first circuit substrate 100C includes a first substrate 110, a first circuit structure 120C, a second circuit structure 130C, a first embedded die 140 and first through substrate vias 310B. The first embedded die 140 is embedded in the first substrate 110. For example, the first substrate 110 has a first cavity, wherein the first cavity is filled with the first insulation structure 122, and the first embedded die 140 is embedded in the first insulation structure 122.

The first circuit structure 120C is located over the first substrate 110 and the first embedded die 140. The first circuit structure 120C includes a first conductive layer 124a disposed on the first substrate 110. The second circuit structure 130C is underlying the first substrate 110. The second circuit structure 130C includes a second conductive layer 134a disposed on the first substrate 110. The first through substrate vias 310B extend through the first substrate 110 and connect the first circuit structure 120C to the second circuit structure 130C.

The second circuit substrate 200C includes a second substrate 210, a third circuit structure 220C, a fourth circuit structure 230C, second through substrate vias 310C and third through substrate vias 310D.

The third circuit structure 220C is located over the second substrate 210. The third circuit structure 220C includes a fifth conductive layer 224a, a seventh conductive layer 224b and vias 226. The fifth conductive layer 224a is disposed on the second substrate 210. A third insulation structure 222 is disposed over the fifth conductive layer 224a. The seventh conductive layer 224b is disposed over the third insulation structure 222 and electrically connected to the fifth conductive layer 224a through the vias 226 in the third insulation structure 222. The fifth conductive layer 224a includes bonding pads for bonding with the first embedded die 140. The bonding pads are disposed between the second substrate 210 and the first embedded die 140.

The fourth circuit structure 230C is under the second substrate 210. The fourth circuit structure 230C includes a sixth conductive layer 234a disposed on the fourth insulation structure 232. The second through substrate vias 310C extend through the second substrate 210 and the fourth insulation structure 232. The second through substrate vias 310C connects the sixth conductive layer 234a to the fifth conductive layer 224a. At least a portion of the second through substrate vias 310C overlaps with and electrically connected to the first embedded die 140. The third through substrate via 310D extend through the bonding layer 300C, the third insulation structure 222, the second substrate 210 and the fourth insulation structure 232. The third through substrate via 310D connects the second conductive layer 134a to the sixth conductive layer 234a. In some embodiments, the third through substrate via 310D overlaps with the first through substrate vias 310B.

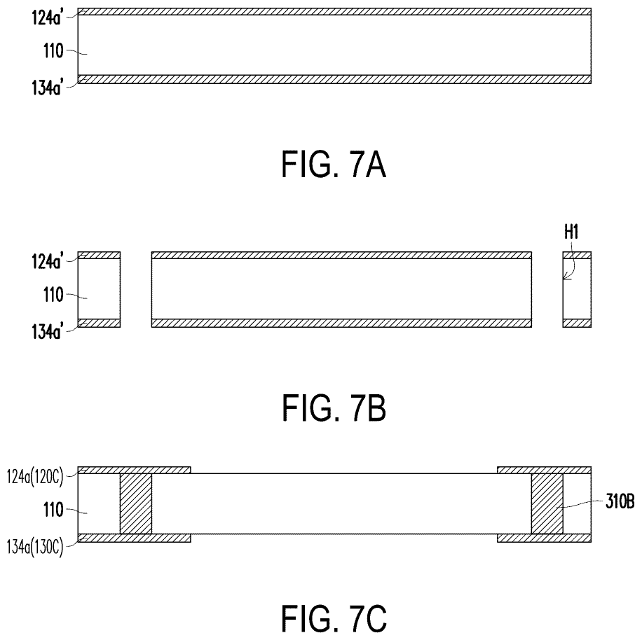

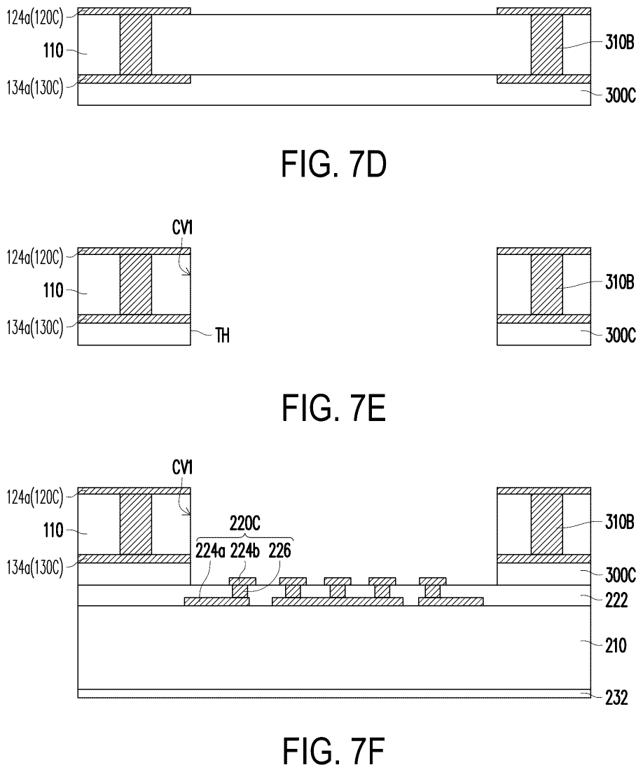

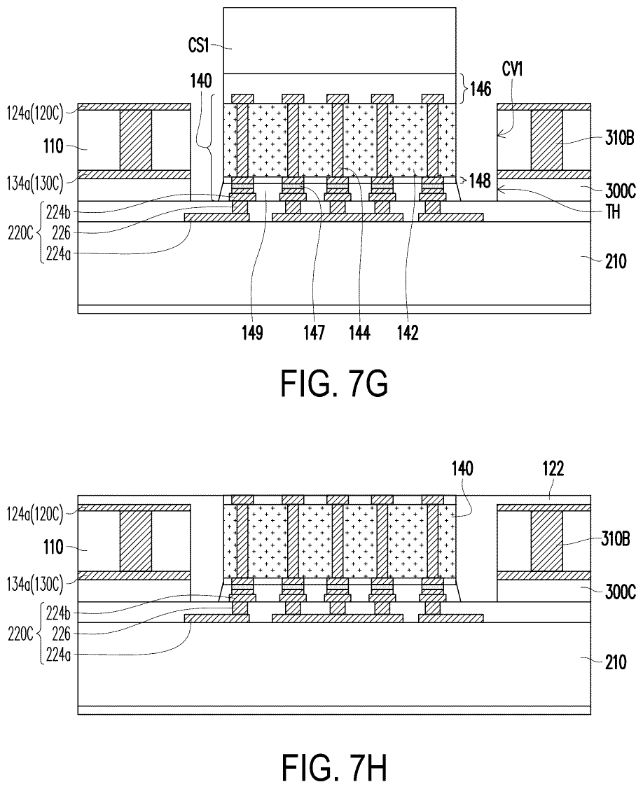

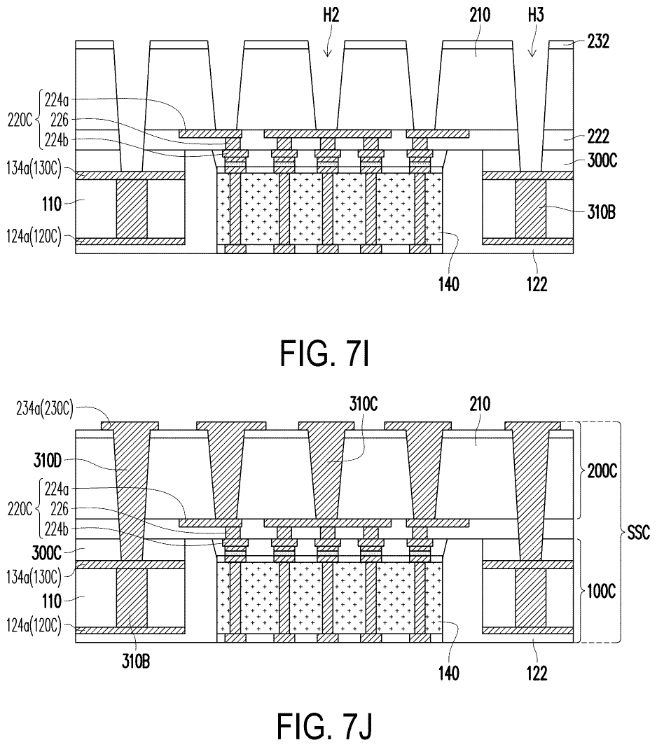

FIGS. 7A to 7J are cross-sectional views of various steps of a fabrication method of the substrate stack SSC in accordance of some embodiments of the disclosure. Referring to FIG. 7A, a first substrate 110 is provided. In some embodiments, the first substrate 110 is a glass substrate. A first conductive material layer 124a′ and a second conductive material layer 134a′ are respectively formed on opposite sides of the first substrate 110.

Referring to FIG. 7B, multiple through holes H1 are formed that pass through the first substrate 110, the first conductive material layer 124a′ and the second conductive material layer 134a′.

Referring to FIG. 7C, a conductive material is filled into the through holes H1, forming the first through substrate vias 310B. Subsequently, the first conductive material layer 124a′ and the second conductive material layer 134a′ are patterned to respectively form the first conductive layer 124a and the second conductive layer 134a on both sides of the first substrate 110.

Referring to FIG. 7D, a bonding layer 300C is formed on the first substrate 110 and covers the second conductive layer 134a.

Referring to FIG. 7E, a first cavity CV1 is formed in the first substrate 110, and a through hole TH is created in the bonding layer 300C, where the first cavity CV1 and the through hole TH are aligned and overlap with one another. In some embodiments, the first cavity CV1 and the through hole TH may be created through laser drilling, mechanical drilling, etching, or other suitable methods. The width and shape of the first cavity CV1 and the through hole TH may be adjusted according to requirements.

Referring to FIG. 7F, the first substrate 110 is bonded to the second substrate 210 by the bonding layer 300C. In some embodiments, the second conductive layer 134a is bonded to the third insulation structure 222. At least a portion of the seventh conductive layer 224b is exposed by the first cavity CV1 and the through hole TH.

Referring to FIG. 7G, the first embedded die 140 is provided. The first embedded die 140 is placed in the first cavity CV1 and the through hole TH. For example, the first embedded die 140 is aligned with the position of the first cavity CV1 through a pick-and-place (PnP) process.

In some embodiments, the first embedded die 140 includes a semiconductor substrate 142, a first interconnecting structure 146, and a second interconnecting structure 148. The first interconnecting structure 146 and the second interconnecting structure 148 are located on opposite sides of the semiconductor substrate 142. Both the first and second interconnecting structures 146 and 148 comprise one or more metal layers and one or more dielectric layers. In some embodiments, the first embedded die 140 includes through-semiconductor vias 144 that extend through the semiconductor substrate 142, electrically connecting the first interconnecting structure 146 to the second interconnecting structure 148.

The second interconnecting structure 148 is bonded to the seventh conductive layer 224b of the third circuit structure 220C. For example, this bonding is achieved through connection terminals 147, which may include BGA connectors, solder balls, metal pillars, C4 bumps, micro bumps, ENEPIG formed bumps, or similar components. After bonding the first embedded die 140 to the third circuit structure 220C, an underfill material 149 is introduced between the first embedded die 140 and the third circuit structure 220C to protect the connection terminals 147.

In some embodiments, a carrier substrate CS1 is positioned on top of the first embedded die 140. For example, the carrier substrate CS1 is bonded to the first interconnecting structure 146 of the first embedded die 140. In certain embodiments, the carrier substrate CS1 is attached to the first embedded die 140 through hybrid bonding, fusion bonding, adhesion, or other suitable methods. The presence of the carrier substrate CS1 helps reduce the likelihood of damage to the first embedded die 140 during the manufacturing process.

Referring to FIG. 7H, a grinding process is performed to remove the carrier substrate CS1 and to expose the uppermost metal layer in the first interconnecting structure 146. In some embodiments, a portion of the dielectric layer within the first interconnecting structure 146 may also be removed during the grinding process. In other embodiments, if the uppermost metal layer in the first interconnecting structure 146 has already been exposed when the first embedded die 140 was placed on the third circuit structure 220C, the grinding process may be omitted.

The first insulation structure 122 is formed within the first cavity CV1, surrounding the first embedded die 140 and the underfill material 149. The first insulation structure 122 is disposed above the first conductive layer 124a and the third circuit structure 220C. A portion of the first insulation structure 122 fills the gap between the first embedded die 140 and the first substrate 110, and is laterally located between a sidewall of the first cavity CV1 and the first embedded die 140.

In some embodiments, a grinding process is performed. Therefore, the top surface of the first insulation structure 122 is coplanar with the top surface of the first embedded die 140.

Referring to FIG. 7I and FIG. 7H, multiple through holes H2 and H3 are formed, passing through the fourth insulation structure 232 and the second substrate 210, wherein the through holes H3 further extend through the third insulation structure 222 and the bonding layer 300C. The through holes H2 expose the fifth conductive layer 224a of the third circuit structure 220C, while the through holes H3 expose the second conductive layer 134a of the second circuit structure 130C. In some embodiments, the through holes H2 overlap the first embedded die 140, while the through holes H3 overlap the first through substrate vias 310B.

Referring to FIG. 7J, a conductive material is filled into the through holes H2 and H3 to form the second through substrate vias 310C and the third through substrate vias 310D. The second through substrate vias 310C overlap with the first embedded die 140, and the third through substrate vias 310D overlap with the first through substrate vias 310B.

The fourth circuit structure 230C, including the sixth conductive layer 234a, is formed over the fourth insulation structure 232. After that, the substrate stack SSC shown in FIG. 6 is substantially completed. Subsequently, the steps described in FIG. 2L to FIG. 2O are performed on the substrate stack SSC to obtain the package structure 1E as shown in FIG. 6.

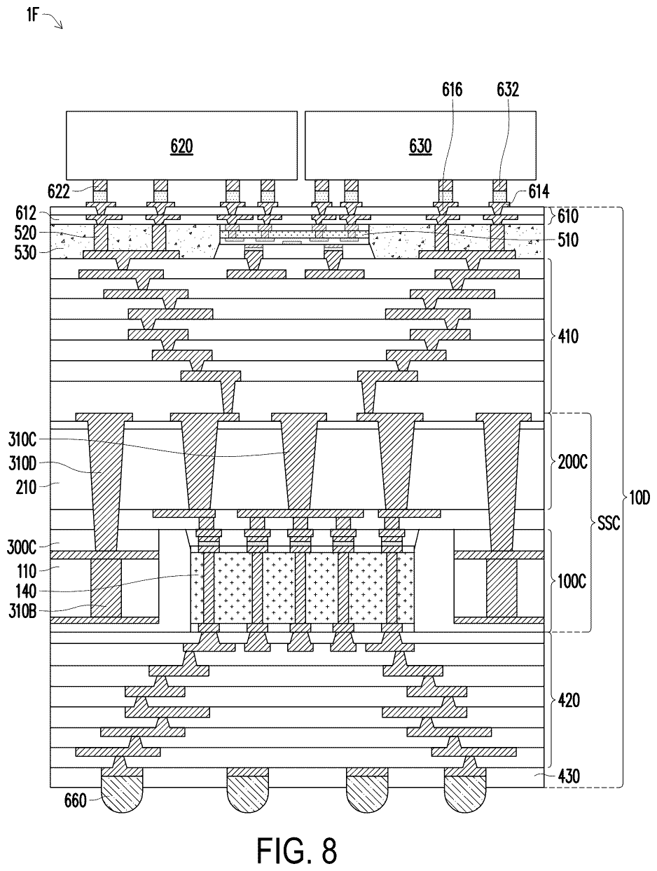

FIG. 8 is a cross-sectional view of a package structure 1F in accordance with some embodiments of the disclosure. The package structure 1F in FIG. 8 is similar to the package structure 1E in FIG. 6, with the difference being that: in the package structure 1E of FIG. 6, the first substrate 110 is positioned closer to the first top die 620 and the second top die 630 than the second substrate 210. However, in the package structure 1F of FIG. 8, the second substrate 210 is positioned closer to the first top die 620 and the second top die 630 than the first substrate 110. In other words, the orientation of the substrate stack SSC in FIG. 8 is reversed compared to the substrate stack SSC in FIG. 6.

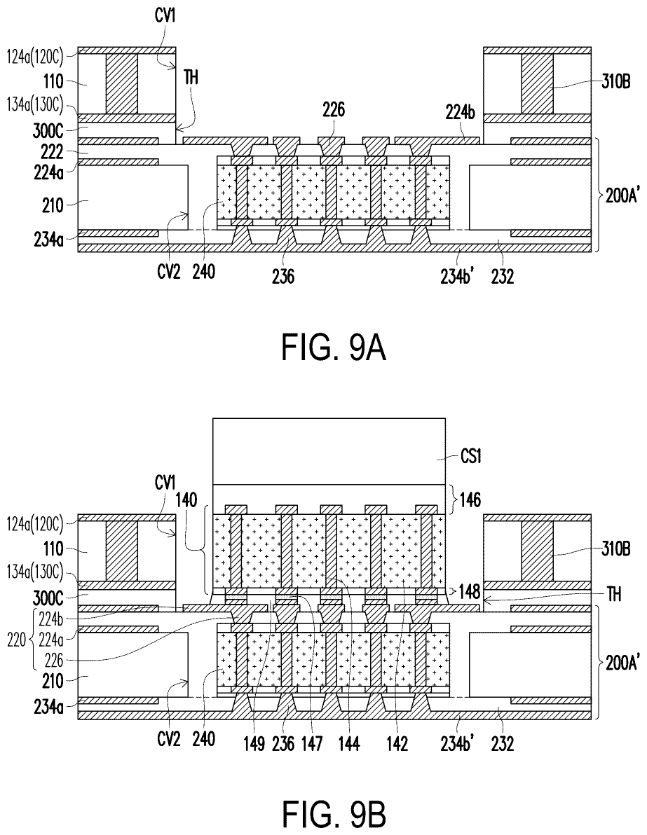

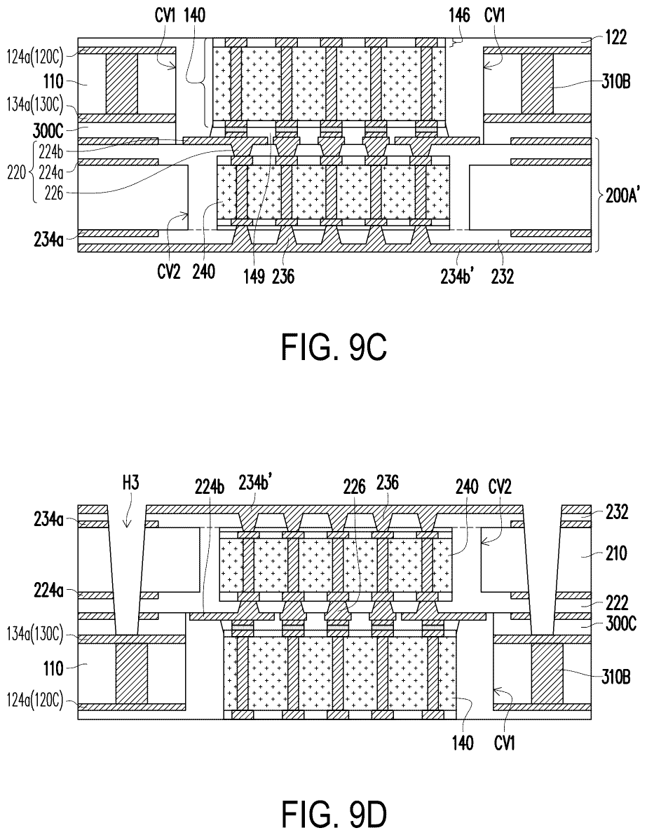

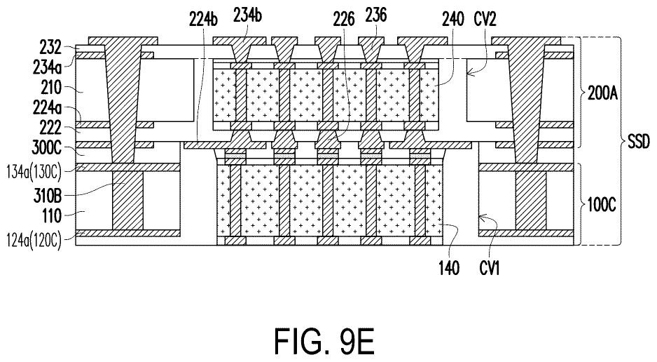

FIGS. 9A to 9E are cross-sectional views illustrating various steps in the fabrication method of a substrate stack SSD in accordance with some embodiments of the disclosure. FIG. 9A follows the steps shown in FIG. 7E, where after forming the first cavity CV1 in the first substrate 110, the first substrate 110 is bonded to the second work piece 200A′ via the bonding layer 300C. The description of the second work piece 200A′ can be referenced in the description related to FIG. 2H.

In some embodiments, the first cavity CV1 of the first substrate 110 and the through hole TH in the bonding layer 300C overlap with the second embedded die 240 in the second work piece 200A′, although this disclosure is not limited thereto.

Referring to FIG. 9B, the first embedded die 140 is provided. The first embedded die 140 is placed in the first cavity CV1. For example, the first embedded die 140 is aligned with the position of the first cavity CV1 and the through hole TH through a pick-and-place (PnP) process.

The second interconnecting structure 148 of the first embedded die 140 is bonded to the seventh conductive layer 224b of the third circuit structure 220. For example, this bonding is achieved through connection terminals 147, which may include BGA connectors, solder balls, metal pillars, C4 bumps, micro bumps, ENEPIG formed bumps, or similar components. After bonding the first embedded die 140 to the third circuit structure 220, an underfill material 149 is introduced between the first embedded die 140 and the third circuit structure 220 to protect the connection terminals 147.

In some embodiments, a carrier substrate CS1 is positioned on top of the first embedded die 140. For example, the carrier substrate CS1 is bonded to the first interconnecting structure 146 of the first embedded die 140.

Referring to FIG. 9C, a grinding process is performed to remove the carrier substrate CS1 and to expose the uppermost metal layer in the first interconnecting structure 146.

The first insulation structure 122 is formed within the first cavity CV1, surrounding the first embedded die 140 and the underfill material 149. The first insulation structure 122 is disposed above the first conductive layer 124a and the third circuit structure 220. A portion of the first insulation structure 122 fills the gap between the first embedded die 140 and the first substrate 110, and is laterally located between a sidewall of the first cavity CV1 and the first embedded die 140.

In some embodiments, a grinding process is performed. Therefore, the top surface of the first insulation structure 122 is coplanar with the top surface of the first embedded die 140.

Referring to FIG. 9C and FIG. 9D, multiple through holes H3 are formed, passing through the fourth insulation structure 232, the second substrate 210, the third insulation structure 222 and the bonding layer 300C. The through holes H3 expose the second conductive layer 134a of the second circuit structure 130C. In some embodiments, the through holes H3 overlap the first through substrate vias 310B.

Referring to FIG. 9E, a conductive material is filled into the through holes H3 to form the third through substrate vias 310D. The third through substrate vias 310D overlap with the first through substrate vias 310B.

The eighth conductive material layer 234b′ is patterned to form the eighth conductive layer 234b. At this stage, a substrate stack SSD, which includes the first circuit substrate 100C and the second circuit substrate 200A, is completed. Subsequently, any of the methods described in the previous embodiments can be applied to form build-up structures, an integrated circuit die, through insulation vias, an encapsulation layer, a redistribution structure, top dies, and conductive terminals on the substrate stack SSD, thereby completing the package structure including the substrate stack SSD.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In accordance with some embodiments of the disclosure, a package structure includes a stacked substrate structure and a second die. The stacked substrate structure includes a first circuit substrate, a second circuit substrate stacked with the first circuit substrate, a first build-up structure located above the first circuit substrate, a first die bonding to the first build-up structure, an encapsulation layer disposed above the first build-up structure and laterally surrounding the first die and a redistribution structure disposed above the encapsulation layer and the first die. The first die includes a through semiconductor via electrically connecting the first build-up structure to the redistribution structure. The second die is disposed above the stacked substrate structure and electrically connected with the redistribution structure.

In accordance with some embodiments of the disclosure, a package structure includes a stacked substrate structure and a second die. The stacked substrate structure includes a first substrate, a second substrate stacked with the first substrate, a bonding layer disposed between the first substrate and the second substrate, a first insulation structure and a first die. The first insulation structure and the first die are located in a first cavity of the first substrate. The first insulation structure is laterally disposed between a sidewall of the first cavity and the first die. The second die is electrically connected with the stacked substrate structure.

In accordance with some alternative embodiments of the disclosure, a fabrication method of a package structure includes forming a stacked substrate structure and providing a first top die over the stacked substrate structure, wherein the first top die is electrically connected to the stacked substrate structure. A method of forming the stacked substrate structure includes the following steps. A first cavity is formed in a first substrate. A first embedded die is provided in the first cavity. A first insulation structure is formed in the first cavity and surrounding the first embedded die. The first substrate with the first cavity is bonded to a second substrate. A first build-up structure is formed above the first substrate and the second substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a stacked substrate structure, comprising:
a first circuit substrate and a second circuit substrate stacked with the first circuit substrate;
a first build-up structure, located above the first circuit substrate;
a first die, bonding to the first build-up structure;
an encapsulation layer, disposed above the first build-up structure and laterally surrounding the first die; and
a redistribution structure, disposed above the encapsulation layer and the first die, wherein the first die comprises a through semiconductor via electrically connecting the first build-up structure to the redistribution structure; and
a second die, disposed above the stacked substrate structure, and electrically connected with the redistribution structure.

2. The package structure of claim 1, wherein the first circuit substrate comprises:
a first glass substrate having a first cavity; and
a first insulation structure and a third die, located in the first cavity, wherein the third die is embedded in the first insulation structure.

3. The package structure of claim 2, wherein the second circuit substrate comprises:
a second glass substrate having a second cavity; and
a second insulation structure and a fourth die, located in the second cavity, wherein the fourth die is embedded in the second insulation structure and overlaps with the third die.

4. The package structure of claim 2, wherein the second circuit substrate comprises:
a second glass substrate;
a bonding pad, disposed between the second glass substrate and the third die, wherein the third die is bonded to the bonding pad.

5. The package structure of claim 4, wherein the first circuit substrate comprises:
a first through substrate via, extending through the first glass substrate; and
a second through substrate via and a third through substrate via, extending through the second glass substrate, wherein the second through substrate via overlaps with the third die, and the third through substrate via overlaps with the first through substrate via.

6. The package structure of claim 1, wherein the stacked substrate structure further comprises:
a bonding layer, disposed between the first circuit substrate and the second circuit substrate; and
a first through substrate via extends through the first circuit substrate, the bonding layer and the second circuit substrate; and
a second build-up structure, located under the second circuit substrate and electrically connected to the first build-up structure through the first through substrate via.

7. The package structure of claim 1, wherein the stacked substrate structure further comprises:
a through insulation via, embedded in the encapsulation layer, wherein the through insulation via electrically connects the first build-up structure to the redistribution structure.

8. The package structure of claim 1, wherein the first circuit substrate further comprises:
a first glass substrate; and
a third die, located in a first cavity of the first glass substrate, wherein the first circuit substrate is bonded to the second circuit substrate through a bonding layer having a through hole, wherein the through hole of the bonding layer overlaps with the first cavity.

9. A package structure, comprising:
a stacked substrate structure, comprising:
a first substrate and a second substrate stacked with the first substrate;
a bonding layer, disposed between the first substrate and the second substrate; and
a first insulation structure and a first die, located in a first cavity of the first substrate, wherein the first insulation structure is laterally disposed between a sidewall of the first cavity and the first die; and
a second die, electrically connected with the stacked substrate structure.

10. The package structure of claim 9, further comprising:
a third die; and
an interposer, located between the second die and the stacked substrate structure and between the third die and the stacked substrate structure.

11. The package structure of claim 9, wherein the stacked substrate structure further comprises:
a third die, located in a second cavity of the second substrate, wherein the first die overlaps with the third die.

12. The package structure of claim 9, wherein the stacked substrate structure further comprises:
a bonding layer, disposed between the first substrate and the second substrate; and
a first through substrate via, extending through the first substrate, the bonding layer and the second substrate.

13. The package structure of claim 9, wherein the stacked substrate structure further comprises:
a first build-up structure, disposed above the first substrate and the second substrate;
an encapsulation layer, disposed above the first build-up structure;
a redistribution structure, disposed above the encapsulation layer; and
an integrated circuit die, embedded in the encapsulation layer, wherein the integrated circuit die comprising a through semiconductor via electrically connecting the first build-up structure to the redistribution structure.

14. The package structure of claim 9, wherein the stacked substrate structure further comprises a second through substrate via extending through the second substrate, wherein the second through substrate via overlaps with and is electrically connected to first die.

15. The package structure of claim 14, wherein the first substrate is closer to the second die than the second substrate.

16. The package structure of claim 14, wherein the second substrate is closer to the second die than the first substrate.

17. A fabrication method of a package structure, comprising:
forming a stacked substrate structure, wherein a method of forming the stacked substrate structure comprises:
forming a first cavity in a first substrate;
providing a first embedded die in the first cavity;
forming a first insulation structure in the first cavity and surrounding the first embedded die;
bonding the first substrate with the first cavity to a second substrate; and
forming a first build-up structure above the first substrate and the second substrate; and
providing a first top die over the stacked substrate structure, wherein the first top die is electrically connected to the stacked substrate structure.

18. The fabrication method of claim 17, wherein the method of forming the stacked substrate structure further comprising:
bonding the first substrate to a tape;
providing the first embedded die in the first cavity above the tape;
forming the first insulation structure in the first cavity and surrounding the first embedded die;
removing the tape; and
bonding the first substrate with the first cavity to the second substrate by a bonding layer.

19. The fabrication method of claim 17, wherein the method of forming the stacked substrate structure further comprising:
forming a bonding layer on the first substrate;
forming the first cavity in the first substrate and forming a through hole in the bonding layer, wherein the first cavity and the through hole are overlapped with each other;
bonding the first substrate to a second substrate by the bonding layer;
providing the first embedded die in the first cavity; and
forming the first insulation structure in the first cavity and surrounding the first embedded die.

20. The fabrication method of claim 19, wherein the method of forming the stacked substrate structure further comprising:
forming a first through substrate via in the first substrate before bonding the first substrate to the second substrate; and
forming a second through substrate via and a third through substrate via in the second substrate after bonding the first substrate to the second substrate, wherein the second through substrate via overlaps with the first embedded die, and the third through substrate via overlaps with the first through substrate via.
